(19) United States
(12) Patent Application Publication
(10) Pub. No.: US 2026/0182185 A1
(43) Pub. Date: Jun. 25, 2026

(54) DISPLAY DEVICE

(71) Applicant: LG Display Co., Ltd., Seoul (KR)

(72) Inventor: DoSung Kim, Paju-si (KR)

(73) Assignee: LG Display Co., Ltd., Seoul (KR)

(21) Appl. No.: 19/402,600

(22) Filed: Nov. 26, 2025

(30) Foreign Application Priority Data
Dec. 24, 2024 (KR) 10-2024-0195066

(51) Int. Cl. H10K 59/131; G09G 3/00; H10K 59/12

(52) U.S. Cl. CPC H10K 59/131; G09G 3/006; H10K 59/1201; G09G 2330/06; G09G 2330/12

(57) ABSTRACT

An electroluminescent display device is provided with light emitting pixels connected to a plurality of first signal lines and second signal lines in a display area, a plurality of pad electrodes in the non-display area, a plurality of link lines disposed in the non-display area and electrically connecting respective pad electrodes and first signal lines, and a low power supply voltage contact part in the non-display area spaced apart from plurality of link lines in plan view. Also, an electrode covers the low power supply voltage contact part electrically connecting the low power supply voltage contact part to cathode electrodes of the light emitting pixels, and a shielding line is disposed between the plurality of link lines and the low power supply voltage contact part and shielding an influence of a voltage applied to the low power supply voltage contact part.

### CROSS-REFERENCE TO RELATED APPLICATIONS

This application claims priority to the Republic of Korea Patent Application No. 10-2024-0195066, filed on Dec. 24, 2024, which is hereby incorporated by reference in its entirety.

### BACKGROUND

### Field of Technology

The present disclosure relates to a display device.

### Description of the Related Art

As an information society develops, a demand for a display device for displaying an image is increasing in various forms. Accordingly, in recent years, various display devices such as a liquid crystal display (LCD), a plasma display panel (PDP), and an organic light emitting display (OLED) have been used. Among the display devices, the organic light emitting display device is a self-luminous type, and has superior viewing angle and contrast ratio compared to the liquid crystal display (LCD), is lightweight and thin because a separate backlight is not required, and power consumption is advantageous. In addition, the organic light emitting display device is driven with a direct current (DC) low voltage, has a fast response speed, and has an advantage of low manufacturing cost.

Internal to display devices, a plurality of signal lines are disposed in a non-display area of the display device, a low power supply voltage contact part having a relatively large area is disposed near the plurality of signal lines, and static electricity can remain in the low power supply voltage contact part during a manufacturing process. Accordingly, an irregular signal can be applied to the plurality of signal lines due to static electricity, which can cause a threshold voltage Vth of a thin film transistor disposed in a number of pixels of a display area to change. As a result, when a finished display device is driven, a shape of a line or a stain can appear at the display device according to a change of the threshold voltage Vth, thereby causing a problem of impairing a user's visual sense.

### SUMMARY OF THE DISCLOSURE

The present disclosure has been made in view of the above problems and it is an aspect of the present disclosure to provide a display device having a shielding line between a low power supply voltage line and a plurality of data line and minimizes or removes fluctuations in a threshold voltage of a driving thin film transistor disposed in each pixel by static electricity generated during an inspection stage. In accordance with an aspect of the present disclosure, the above and other technical effects can be accomplished by the provision of an electroluminescent display device including a substrate including a display area and a non-display area, a plurality of first signal lines in the display area, a plurality of second signal lines disposed in the display area and extending in a direction perpendicular to the plurality of first signal lines, a plurality of pad electrodes in the non-display area, a plurality of link lines disposed in the non-display area and electrically connected to the plurality of pad electrodes and the plurality of first signal lines, a low power supply voltage contact part in the non-display area, and a shielding line between the plurality of link lines and the low power supply voltage contact part

In addition, in accordance with an aspect of the present disclosure, the above and other technical effects can be accomplished by the provision of an electroluminescent display device including a substrate including a display area and a non-display area, a low power supply voltage contact part disposed in the non-display area, a low power supply voltage line disposed in the non-display area and connected to the low power supply voltage contact part. Further, a bridge line is disposed in the non-display area and connected to the low power supply voltage contact part, and a pad electrode is connected to the low power supply voltage line while not connected to the bridge line. It is to be understood both the foregoing general description and the following detailed description are exemplary and explanatory and are intended to provide further explanation of the inventive concepts as claimed

### BRIEF DESCRIPTION OF THE DRAWINGS

The accompanying drawings, which are included to provide a further understanding of the disclosure and are incorporated in and constitute a part of this application, illustrate embodiments of the disclosure and together with the description explain the principle of the disclosure. In the drawings:

FIG. 1 is a schematic perspective view of a display device according to an embodiment of the present disclosure.

FIG. 2 is a schematic plan view of a display device according to an embodiment of the present disclosure.

FIG. 3 is a circuit diagram of one pixel disposed in a display device according to an embodiment of the present disclosure.

FIG. 4 is a plan view of a display device according to an embodiment of the present disclosure.

FIGS. 5A and 5B are process plan views for manufacturing a display device according to an embodiment of the present disclosure.

FIG. 6 is a cross-sectional view of a display device according to an embodiment of the present disclosure and relates to a cross section I-I′ of FIG. 4 and a cross section of any one pixel.

FIGS. 7A and 7B are plan views of a display device before a cutting process according to an embodiment of the present disclosure, and FIGS. 7C and 7D are plan views of a display device after the cutting process according to an embodiment of the present disclosure.

FIGS. 7E and 7F are plan views of a display device according to another embodiment of the present disclosure.

FIG. 8 is a plan view of a display device according to another embodiment of the present disclosure.

FIG. 9 is a plan view of a display device according to another embodiment of the present disclosure.

FIG. 10 is a cross-sectional view of a display device according to another embodiment of the present disclosure, and relates to a cross section II-II′ of FIG. 9.

FIG. 11 is a plan view of a display device according to another embodiment of the present disclosure.

FIG. 12 is a cross-sectional view of a display device according to another embodiment of the present disclosure, and relates to a cross section III-III′ of FIG. 11.

FIG. 13 is a plan view of a display device according to another embodiment of the present disclosure.

FIG. 14 is a plan view of a display device according to another embodiment of the present disclosure.

FIG. 15 is a plan view of a display device according to another embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. The progression of processing steps and/or operations described is an example; however, the sequence of steps and/or operations is not limited to examples set forth herein and can be changed as is known in the art, with the exception of steps and/or operations necessarily occurring in a particular order. Names of the respective elements used in the following explanations can be selected only for convenience of writing the specification and can be thus different from those used in actual products.

Advantages and features of the present disclosure, and implementation methods thereof, will be clarified through the following examples described with reference to the accompanying drawings. The present disclosure may, however, be embodied in different forms and should not be construed as limited to the examples set forth herein. Rather, these examples are provided so the specification of the present disclosure will be thorough, complete, and fully convey the scope of the present disclosure to those skilled in the art. Further, the scope of the present disclosure is only defined by of the accompanying claims.

A shape, a size, a ratio, an angle, and a number disclosed in the accompanying drawings for describing the examples of the present disclosure are merely illustrative and, thus, the present disclosure is not limited to the illustrated details. Unless stated otherwise, like reference numerals refer to like elements throughout the specification. In the following description, when the detailed description of the relevant known function or configuration is determined to unnecessarily obscure an important point of the present disclosure, the detailed description will be omitted. In examples where ‘comprise,’ ‘have,’ and ‘include’ are used, another portion can be added unless ‘only’ is used. The terms of a singular form can include plural forms unless referred to the contrary.

In interpreting the components, it is interpreted as including an error range even if there is no separate explicit description of an error range. In describing a position relationship, for example, when the position relationship is described as ‘upon,’ ‘above,’ ‘below,’ and ‘next to,’ one or more portions can be disposed between two other portions unless ‘just’ or ‘direct’ is used. The terms, such as “below,” “lower,” “above,” “upper,” and the like, can be used herein to describe a relationship between elements as illustrated in the drawings. These terms are spatially relative and based on the orientation depicted in the drawings.

A description of a time relationship can include an example in which the temporal precedence relationship is described as “after,” “following,” or “before,” etc., and is not continuous unless “right away” or “directly,” is used. Although the first, second, and the like are used to describe various components, these components are not limited by these terms. These terms are used only to distinguish one component from another. Therefore, a first component mentioned below can be a second component within a technical idea of a present disclosure.

In this disclosure, although the terms “first,” “second,” “A,” “B,” “(a),” and “(b),” etc., can be used herein to describe various elements, these elements should not be limited by these terms. These terms are only used to distinguish one element from another. For example, a first element could be termed a second element, and, similarly, a second element could be termed a first element, without departing from the scope of the present disclosure.

If a component is stated to be “connected,” “coupled,” or “attached” to another component, such component can be connected, coupled, or attached directly to the other component, but it should also be understood other components can be interposed between such components described as connected, coupled, or attached indirectly, without any specific description. Also, if a component or layer is stated to be “in contact” or “overlapping” with another component or layer, the component or layer can be in direct contact or overlapping with another component or layer, but other components can be interposed between the components described as indirectly in contact or overlapping without explicit description. Further, the term “at least one” should be understood as including any and all combinations of one or more of the associated listed items. For example, the meaning of “at least one of a first element, a second element, or a third element” compasses the combination of all three listed elements, combinations of any two of the three elements, as well as each individual element, the first element, the second element, or the third element.

An addition, the terms “first direction,” “second direction,” “third direction,” “X-axis direction,” “Y-axis direction,” should not be interpreted only as a geometric relationship perpendicular to each other, but can mean a particular configuration of has a wider direction within a range in which the configuration of the present disclosure can functionally act. Also, features of each of the various examples of the present disclosure can be partially or entirely coupled or combined with each other, technically various interworking and driving are possible, and each of the examples can be independently implemented with respect to each other or can be implemented together in a related relationship. Hereinafter, one embodiment of the present disclosure will be described in detail with reference to the accompanying drawings.

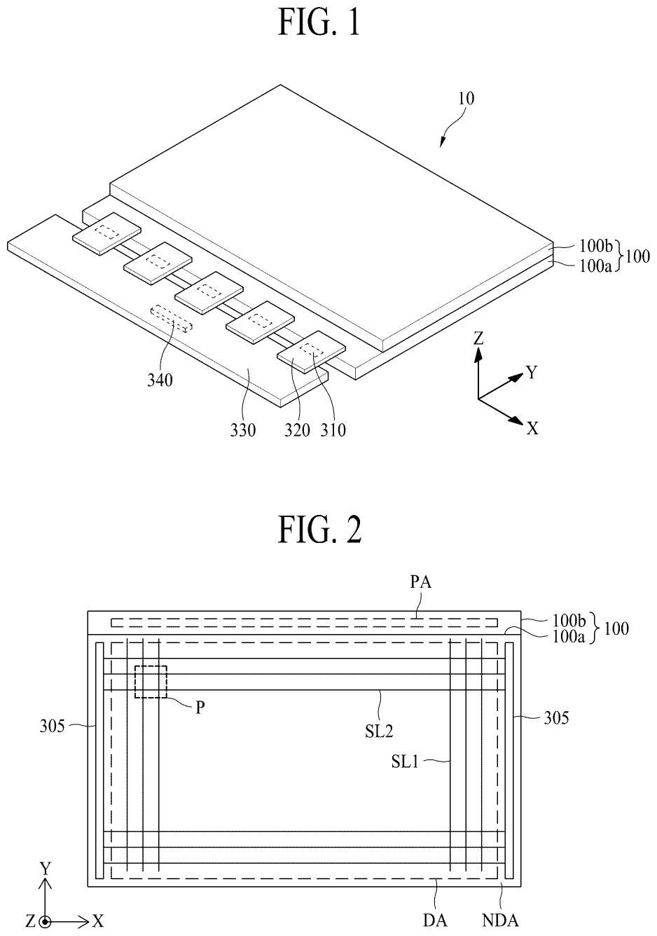

FIG. 1 is a schematic perspective view of a display device according to an embodiment of the present disclosure, and FIG. 2 is a schematic plan view of a display device according to an embodiment of the present disclosure. Hereinafter, an X-axis represents a direction parallel to a gate line, a Y-axis represents a direction parallel to a data line, and a Z-axis represents a height direction/thickness of a display device 10. Although the display device 10 according to an embodiment is mainly implemented as an organic light emitting display, it can be implemented as a liquid crystal display (Liquid Crystal Display), a plasma display (PDP), a quantum dot light emitting display (QLED), or an electrophoretic display.

Referring to FIGS. 1 and 2, the display device 10 includes a display panel 100, a source drive integrated circuit (hereinafter referred to as an “source drive IC”) 310, a flexible film 320, a circuit board 330, and a timing control unit (hereinafter may also be referred to as timing controller) 340. In addition, the display panel 100 includes a first substrate 100a and a second substrate 100b facing each other. The second substrate 100b can be an encapsulation substrate, and the first substrate 100a can be a plastic film, a glass substrate, or a silicon wafer substrate formed by using a semiconductor process. Similarly, the second substrate 100b can be a plastic film, a glass substrate, or an encapsulation film. Also, the first substrate 100a and the second substrate 100b can be formed of a transparent material. Further, the display panel 100 can be divided into a display area DA in which pixels are formed to display an image and a non-display area NDA in which an image is not displayed.

As is shown in FIG. 2, a plurality of vertical signal lines (hereinafter may also be referred to as first signal lines) SL1, a plurality of horizontal signal lines (hereinafter may also be referred to as second signal lines) SL2, and a plurality of pixels P can be disposed in the display area DA. Also, a pad area PA in which pads are disposed and at least one gate driver 305 can be disposed in the non-display area NDA. FIG. 2 also shows the gate driver 305 being disposed at one side and the other side of the display panel 100, respectively, but the present disclosure is not limited thereto. Also, the vertical signal lines SL1 can extend in a second direction (e.g., the Y-axis direction), and can cross the horizontal signal lines SL2 in the display area DA. Further, the vertical signal lines SL1 can be, for example, high power supply voltage lines for supplying a high power supply voltage to an anode, reference voltage lines for transmitting a reference signal to each of the pixels P, data lines for transmitting a data signal to each of the pixels P, and the like, but are not limited thereto. Also the vertical signal lines SL1 can be one of various lines for transmitting a signal according to a technology level of an art.

Further, the horizontal signal lines SL2 can extend in a first direction (e.g., the X-axis direction) in the display area DA with the horizontal signal lines SL2 being, for example, gate lines transmitting gate signals to each of the pixels P. However, the horizontal signal lines SL2 are not limited thereto, and can include one of various lines for transmitting a signal according to the technology level of the art. Also, as shown in FIG. 2, the pixels P are disposed in an area in which the first signal lines SL1 are disposed or in an area in which the first signal lines SL1 and the second signal lines SL2 cross, and emit predetermined light to display an image.

In operation, the source drive IC 310 can receive a digital video data and a source control signal from the timing controller 340. Also, the source drive IC 310 can convert a digital video data into an analog data voltages according to the source control signal, and supply the converted analog data to a data line. When the source drive IC 310 is manufactured as a driving chip, the source drive IC 310 can be mounted on the flexible film 320 by a chip-on-film (COF) or a chip-on-plastic (COP) scheme. Also, lines connecting pads to the source drive IC 310 and lines connecting pads to lines of the circuit board 330 can be formed in the flexible film 320 with the flexible film 320 being attached onto the pads using an anisotropic conducting film, and thus the pads and lines of the flexible film 320 can be connected.

Next, the circuit board 330 can be attached to the flexible films 320, and a plurality of circuits implemented with driving chips can be mounted on the circuit board 330. For example, the timing controller 340 can be mounted on the circuit board 330, and the circuit board 330 can be a printed circuit board or a flexible printed circuit board. In operation, the timing controller 340 can receive a digital video data and a timing signal from an external system board, then generate a gate control signal for controlling an operation timing of the gate driver and a source control signal for controlling the source drive ICs 310 based on the timing signal. Then, the timing controller 340 can supply the gate control signal to the gate driver 305, and supply the source control signal to the source drive ICs 310.

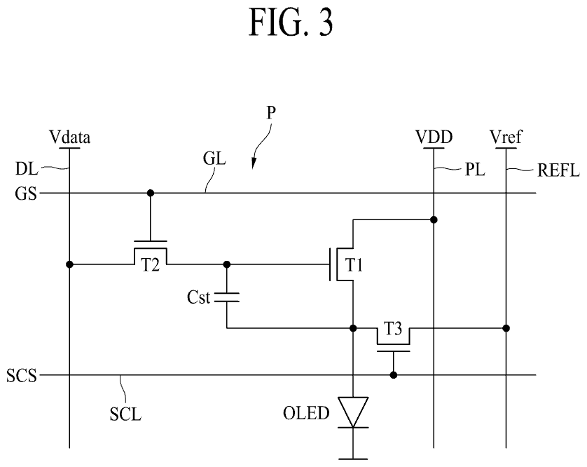

Next, FIG. 3 is a circuit diagram of one pixel disposed in a display device according to an embodiment of the present disclosure. As illustrated in FIG. 3, the pixel P includes first to third thin film transistors T1, T2, and T3, and a capacitor Cst. In various examples, the first thin film transistor T1 is a driving thin film transistor, the second thin film transistor T2 is a switching thin film transistor, and the third thin film transistor T3 is a sensing thin film transistor. In operation, the first thin film transistor T1 is switched according to a data voltage Vdata supplied from the second thin film transistor T2, generates a data current from a driving voltage VDD supplied to a power line PL and supplies a data current to an organic light emitting diode OLED.

Next, the second thin film transistor T2 is switched according to a gate signal GS supplied to a gate line GL and supplies the data voltage Vdata supplied to the data line DL to the first thin film transistor T1. Also, the third thin film transistor T3 is switched according to a sensing control signal SCS supplied to a sensing control line SCL, and accordingly, a threshold voltage of the first thin film transistor T1 is sensed by using a reference voltage Vref supplied to a reference line REFL. In operation, capacitor Cst serves to maintain the data voltage supplied to the first thin film transistor T1 for one frame, and is disposed between a gate electrode and a source electrode of the first thin film transistor T1. Also, the organic light emitting diode OLED emits predetermined light according to the data current supplied from the first thin film transistor T1.

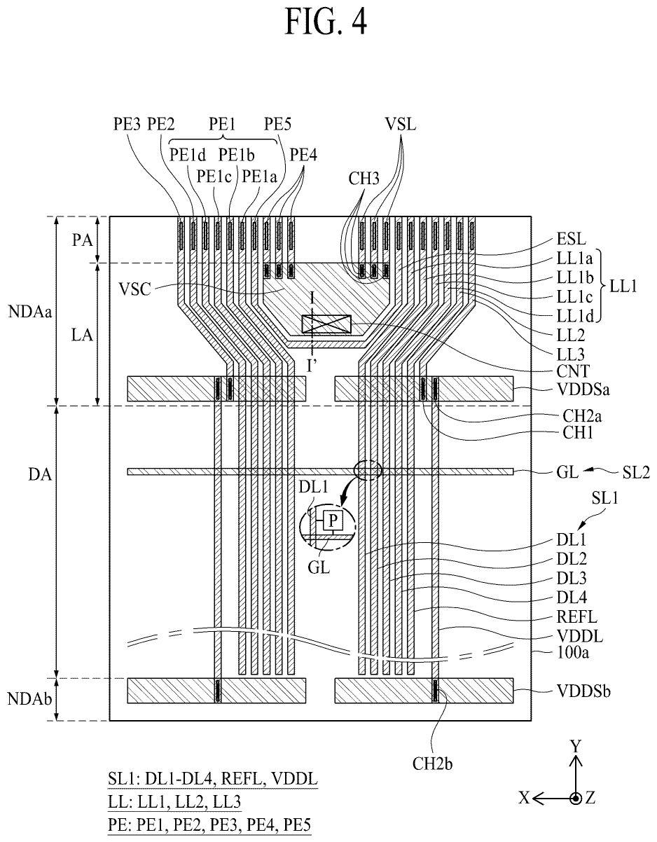

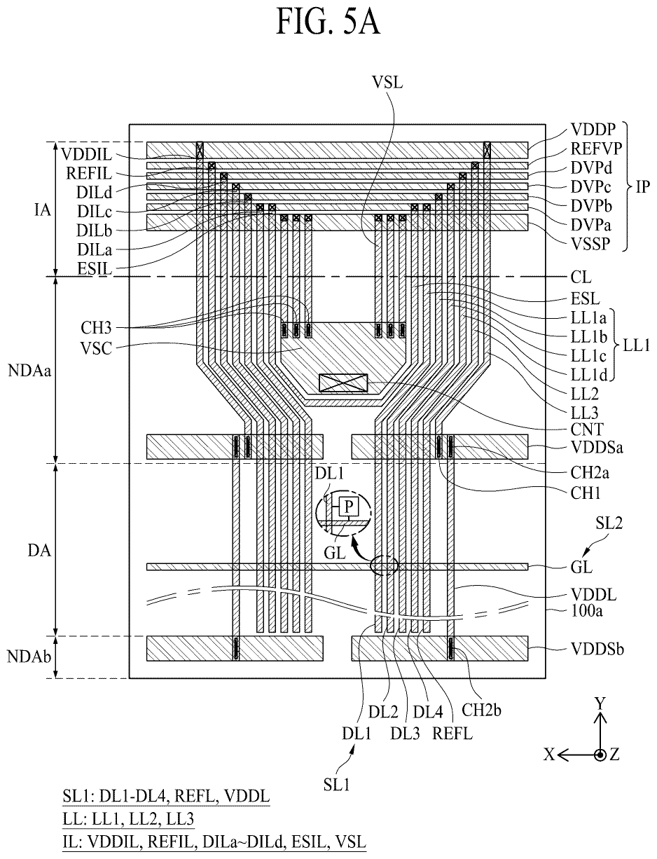

Next, FIG. 4 is a plan view of a display device according to an embodiment of the present disclosure. As shown in FIG. 4, the display device includes a first substrate 100a, a plurality of pad electrodes PE, a plurality of link lines LL, a low power supply voltage contact part VSC, a shielding line ESL, a first high power supply voltage shorting bar VDDSa, a second high power supply voltage shorting bar VDDSb, a plurality of first signal lines SL1, a plurality of second signal lines SL2, and a plurality of pixels P. In the example of FIG. 4, the substrate 100a includes a non-display area NDA and a display area DA with the non-display area NDA defined as an area other than the display area DA among areas defined on the first substrate 100a. Further, various wirings, electrodes, and thin film transistors can be disposed in the non-display area NDA, and various wirings, electrodes, and thin film transistors disposed in the non-display area NDA can transmit signals for implementing an image or a video in the display area DA.

Also, the non-display area NDA can include one side of the display area DA, for example, a first non-display area NDAa disposed at an upper side thereof and the other side of the display area DA, for example, a second non-display area NDAb disposed at a lower side thereof. The first non-display area NDAa and the second non-display area NDAb can be positioned to face each other with respect to the display area DA. Further, the first non-display area NDAa can include a pad area PA and a link area LA, the pad area PA can include the pad electrodes PE configured to receive a plurality of signals transmitted from the flexible film (see 320 of FIG. 1) and transmit the signals to the link lines LL, and the pad electrodes PE can include, for example, a first pad electrode PE1, a second pad electrode PE2, a third pad electrode PE3, a fourth pad electrode PE4, and a fifth pad electrode PE5.

In the example of FIG. 4, the first pad electrode PE1 can apply a data voltage to a data line connected to each of the pixels P, the second pad electrode PE2 can apply a reference voltage to a reference line, the third pad electrode PE3 can be apply a high power supply voltage to the first high power supply voltage shorting bar VDDSa, the fourth pad electrode PE4 can apply a low power supply voltage to a low power supply voltage contact part VSC, and the fifth pad electrode PE5 can apply a voltage to the shielding line ESL. Also shown in FIG. 4, the first pad electrode PE1 includes a 1-1st pad electrode PE1a, a 1-2nd pad electrode PE1b, a 1-3rd pad electrode PE1c, and a 1-4th pad electrode PE1d. In this example, in order to emit light of red (R), green (G), blue (B), and white (W) in the pixels P, each of the 1-1st pad electrode PE1a to the 1-4th pad electrode PE1d can apply the data voltage received from the flexible film (see 320 of FIG. 1) to any one of the first signal lines SL1, for example, any one among a first data line DL1 to a fourth data line DL4. Meanwhile, an arrangement of the 1-1st pad electrode PE1a to the 1-4th pad electrode PE1d is not limited thereto.

Next, the second pad electrode PE2 can apply the reference voltage received from the flexible film 320 (see FIG. 1) to the other first signal line, for example, the reference line REFL among the first signal lines SL1. Further, the third pad electrode PE3 can apply a first power source, for example, a high power supply voltage received from the flexible film (see 320 of FIG. 1), to the first high power supply voltage shorting bar VDDSa. Still further, the fourth pad electrode PE4 can apply a second power source, for example, a low power supply voltage received from the flexible film (see 320 of FIG. 1) to the low power supply voltage contact part VSC. In addition, the fourth pad electrode PE4 can be formed in plural, for example, and as shown in FIG. 4, can be provided as a combination of three left pad electrodes and three right pad electrodes, but a number and arrangement of the fourth pad electrode PE4 and the low power supply voltage contact part VSC are not limited thereto, and can be variously changed according to the technology of the art.

Further, the fifth pad electrode PE5 can apply the first voltage received from the flexible film (see 320 of FIG. 1) to the shielding line ESL, and the shielding line ESL can be maintained so as not to be floated by transmitting the first voltage received from the flexible film (see 320 of FIG. 1) to the shielding line ESL through the fifth pad electrode PE5. In addition, the example link area LA includes the link lines LL, the low power supply voltage contact part VSC, the shielding line ESL, and the first high power supply voltage shorting bar VDDSa. In operation, the link lines LL can transmit signals applied from the pad electrode PE disposed in the pad area PA to the first signal lines SL1 and/or the first high power supply voltage shorting bar VDDSa. In varying examples, the link lines LL can include a first link line LL1, a second link line LL2, and a third link line LL3 with the first link line LL1, the second link line LL2, and the third link line LL3 extending in the second direction Y, for example, a vertical direction, and extending from the first non-display area NDAa toward the display area DA.

In addition, the first link line LL1 can include a 1-1st link line LL1a, a 1-2nd link line LL1b, a 1-3rd link line LL1c, and a 1-4th link line LL1d. Also, the 1-1st link line LL1a to the 1-4th link line LL1d can be electrically connected to the 1-1st pad electrode PE1a to the 1-4th pad electrode PE1d, respectively. For example, in order to emit red (R), green (G), blue (B), or white (W) light in the pixels P, the data voltage received from the flexible film (see 320 of FIG. 1) can be transmitted to any one of the 1-1st link line LL1a to the 1-4th link line LL1d through any one of the first signal lines SL1, for example, any one of the first to fourth data lines DL1 to DL4, through any one of the 1-1st link line LL1a to the 1-4th link line LL1d. Also, the pixels P can be provided to emit red (R), green (G), and blue (B) light except for white (W), and in this example, the first link line LL1 includes a 1-1st link line LL1a, a 1-2nd link line LL1b, and a 1-3rd link line LL1c, and the 1-1st to 1-3th link lines LL1a to LL1c can be connected to the first to third data lines DL1 to DL3, respectively.

Further, the second link line LL2 can be electrically connected to the second pad electrode PE2, and the second link line LL2 can transmit the reference voltage received from the flexible film (see 320 of FIG. 1) to the other first signal line, for example, the reference line REFL, among the first signal lines SL1. However, in some examples, the second link line LL2 may not be disposed, and in this example, the second pad electrode PE2 may not be disposed either. Also, the third link line LL3 can be electrically connected to the third pad electrode PE3, and the third link line LL3 can transmit the first power source, for example, the high power supply voltage, received from the flexible film (see 320 of FIG. 1) to the first high power supply voltage shorting bar VDDSa. For example, the third link line LL3 may be electrically connected to the first high power supply voltage shorting bar VDDSa through a first contact hole CH1.

In addition, the low power supply voltage contact part VSC can be disposed adjacent to the link lines LL, and the low power supply voltage contact part VSC can be formed in a shape of a polygon having a long length of one side, for example, an upper side and a short length of the other side, for example, a lower side, but is not limited thereto. Also, while the low power supply voltage contact part VSC is shown to have a hexagonal shape when viewed in a plan view, but is not limited thereto and can be formed in a shape of an inverted triangle, an inverted trapezoid, or the like.

Further, the low power supply voltage contact part VSC can be connected to a low power supply voltage line VSL extending toward the pad area PA. For example, the low power supply voltage contact part VSC can be electrically connected to the low power supply voltage line VSL through a third contact hole CH3. Also, the low power supply voltage contact part VSC can receive a voltage from the source drive IC 310 connected to the pad area PA and transmit the low power supply voltage to a cathode of the pixel. Specifically, the low power supply voltage contact part VSC can receive the low power supply voltage applied to the fourth pad electrode PE4 disposed in the pad area PA through the low power supply voltage line VSL.

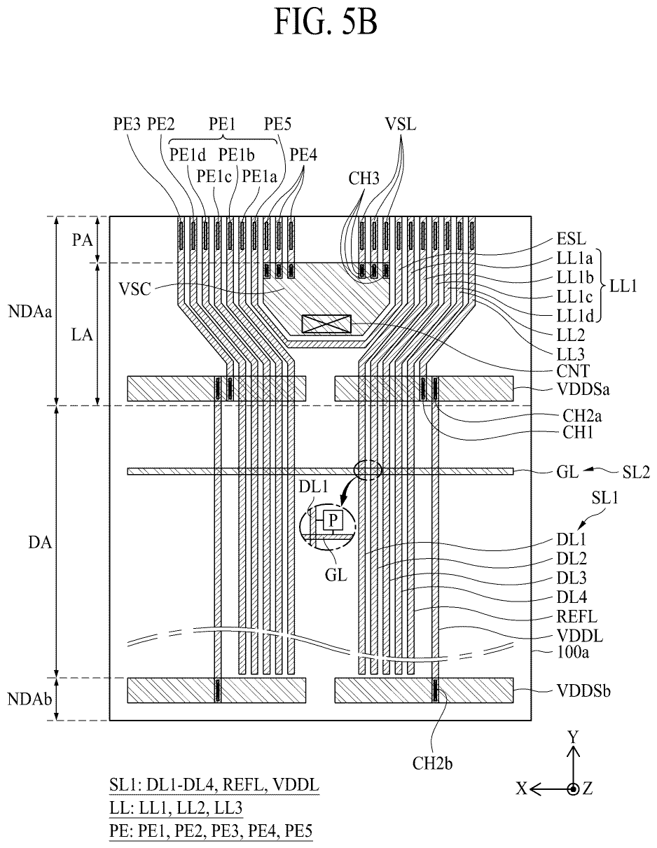

Next, the shielding line ESL can be disposed between the link lines LL and the low power supply voltage contact part VSC. Accordingly, in a process of manufacturing the display device according to an embodiment, it is possible to minimize a voltage applied to the low power supply voltage contact part VSC in an inspection process from affecting the link lines LL. For example, the inspection process can be a process of checking whether a signal such as a data voltage is normally applied to the first signal lines SL1 or checking whether a low power supply voltage is normally applied to the low power supply voltage contact part VSC, but is not limited thereto. Specifically, when a voltage is applied to the low power supply voltage contact part VSC, a threshold voltage Vth of the driving thin film transistor TRd of the pixel connected to the first link line LL1 and the first data line DL1 disposed closest to the low power supply voltage contact part VSC can be varied. However, according to an embodiment, the influence of the voltage applied to the low power supply voltage contact part VSC on the link lines LL in the inspection process can be minimized or removed by the shielding line ESL. A more detailed principle will be described later with reference to FIGS. 5A and 5B.

Thus, by providing the shielding line ESL, fluctuations in the threshold voltage Vth of the driving thin film transistors disposed in the pixels disposed in the display device can be minimized. Accordingly, it is possible to minimize or prevent an occurrence of stains or lines when an image is displayed or reproduced. Also, the shielding line ESL can surround an outer side of the low power supply voltage contact part VSC within the link area LA, an inside of the low power supply voltage contact part VSC can be defined as an inside where a contact part CNT is formed based on a boundary of the low power supply voltage contact part VSC, and an outside of the low power supply voltage contact part VSC can be defined as an outside of the boundary of the low power supply voltage contact part VSC where the contact part CNT is not formed.

Further, the shielding line ESL can receive a voltage from the flexible film (see 320 of FIG. 1) connected to the fifth pad electrode PE5. By forming in this way, interference between the low power supply voltage contact part VSC and the first link line LL1 can be minimized by the shielding line ESL even when the display device is driven. Also, the first high power supply voltage shorting bars VDDSa can extend along the first direction X, with the first high power supply voltage shorting bars VDDSa spaced apart and separated from each other in the first direction X while arranged in a line. However, the present disclosure is not limited thereto, and the first high power supply voltage shorting bar VDDSa can be disposed on the first substrate 100a in the first direction X in the form of a bar.

In addition, the first high power supply voltage shorting bar VDDSa can receive the high power supply voltage transmitted from the third pad electrode PE3 to apply the high power supply voltage to another first signal line, for example, a high power supply voltage line VDDL. In this way, by applying the high power supply voltage using the first high power supply voltage shorting bar VDDSa, a relatively high voltage can be stably applied to the high power supply voltage line VDDL disposed individually in the pixels P. Also, the second non-display area NDAb can include the second high power supply voltage shorting bar VDDSb, which can be electrically connected to the first high power supply voltage shorting bar VDDSa through the high power supply voltage line VDDL among the first signal lines SL1 with the first signal lines SL1, the second signal lines SL2, and the pixels P disposed in the display area DA, which can be an area in which an image or a video is provided by light emitted by the pixels P.

Also, the first signal lines SL1 include first to fourth data lines DL1 to DL4, a reference line REFL, and a high power supply voltage line VDDL. The first data line DL1 to the fourth data line DL4 can extend from the 1-1st link line LL1a to the 1-4th link line LL1d to receive a signal transmitted from the 1-1st pad electrode PE1a to the 1-4th pad electrode PE1d, respectively. Specifically, the first data line DL1 can extend from the 1-1st link line LL1a to receive a signal transmitted from the 1-1st pad electrode PE1a. In the same manner, the second data line DL2 can extend from the 1-2nd link line LL1b to receive a signal transmitted from the 1-2nd pad electrode PE1b, and the third data line DL3 can extend from the 1-3rd link line LL1c to receive a signal transmitted from the 1-3rd pad electrode PE1c, and the fourth data line DL4 can extend from the 1-4th link line LL1d to receive a signal transmitted from the 1-4th pad electrode PE1d. In this example, the first data line DL1 to the fourth data line DL4 can be integrally formed with the 1-1 st link line LL1a to the 1-4th link line LL1d, respectively, but the present disclosure is not limited thereto. Further, the reference line REFL can extend from the second link line LL2 to receive the reference voltage transmitted from the second pad electrode PE2 with the reference line REFL being connected to each of the pixels P. Accordingly, the threshold voltage of the driving thin film transistor (driving TFT) disposed in the pixels P can be sensed.

Next, the high power supply voltage line VDDL can be disposed between the first high power supply voltage shorting bar VDDSa and the second high power supply voltage shorting bar VDDSb. For example, one end, e.g., an upper end, of the high power supply voltage line VDDL can be electrically connected to the first high power supply voltage shorting bar VDDSa through a 2-1st contact hole CH2a, and the other end, e.g., a lower end of the high power supply voltage line VDDL can be electrically connected to the second high power supply voltage shorting bar VDDSb through a 2-2nd contact hole CH2b. Also, the high power supply voltage line VDDL can be disposed between the first high power supply voltage shorting bar VDDSa and the second high power supply voltage shorting bar VDDSb, and a high power supply voltage can be applied to each of the pixels P disposed in the display area DA to provide power for each of the pixels P to emit light.

Also, the second signal lines SL2 include a gate line GL, which can extend along the first direction X, for example, a horizontal direction. The gate line GL can also overlap or intersect the first to fourth data lines DL1 to DL4 while extending along the first direction X, and the pixels P can be disposed in an area formed by crossing the gate line GL and the first to fourth data lines DL1 to DL4. Also, the pixels P can be disposed in an area in which the first signal lines SL1 and the second signal lines SL2 cross each other in the display area DA. For example, each of the pixels P can be supplied with a data voltage from any one of the first data line DL1 to the fourth data line DL4, a gate signal can be supplied from the gate line GL, a reference voltage can be applied from the reference line REFL, and a high power supply voltage can be applied from the high power supply voltage line VDDL.

Next, FIGS. 5A and 5B illustrate plan views for manufacturing a display device according to an embodiment of the present disclosure. In particular, FIGS. 5A and 5B relate to a display device according to an embodiment of FIG. 4. First, as shown in FIG. 5A, in order to manufacture a display device according to an embodiment of the present disclosure, a plurality of link lines LL, a low power supply voltage contact part VSC, a shielding line ESL, a first high power supply voltage shorting bar VDDSa, a second high power supply voltage shorting bar VDDSb, a plurality of first signal lines SL1, a plurality of second signal lines SL2, and a plurality of pixels P can be formed on a first substrate 100a. In the embodiment of FIG. 5A, a pad area (see PA of FIG. 4) is not formed to test whether various lines, electrodes, and thin film transistors disposed in the display device of the present disclosure operate normally. In other words, an inspection area IA can be formed without forming the pad electrode (see PE of FIG. 4) in the link lines LL. In this example, the inspection area IA can be disposed at one side, for example, an upper side, of the first non-display area NDAa. The inspection area IA includes a plurality of inspection parts IP and a plurality of inspection lines IL. The inspection parts IP include a high power supply voltage inspection part VDDP, a first data voltage inspection part DVPa to a fourth data voltage inspection part DVP, a reference voltage inspection part REFVP, and a low power supply voltage inspection part VSSP.

Also, the inspection lines ILs include a high power supply voltage inspection line VDDIL, a first data voltage inspection line DILa to a fourth data voltage inspection line DILd, a reference voltage inspection line REFIL, a shielding inspection line ESIL, and a low power supply voltage line VSL. The first data inspection line DILa to a fourth data voltage inspection line DILd can be formed identically in a process of forming a 1-1st to a 1-4th link line LL1a to LL1d, the reference voltage inspection line REFIL can be formed identically in a process of forming a second link line LL2, and the high power supply voltage inspection line VDDIL can be formed identically in a process of forming a third link line LL3.

Next, by applying a voltage to various lines, electrodes, and thin film transistors disposed in the non-display area NDA and the display area DA, the inspection area IA can check in advance whether each component disposed in the display device operates normally before completion to lower a defect rate of a completed product and improve a yield. Specifically, each of the inspection parts IP disposed in the inspection area IA can be electrically connected to the link lines LL and/or the low power supply voltage line VSL through the inspection lines IL. In this example, some of the inspection parts IP can check whether signals are normally applied to the first signal lines SL1 and the pixels P disposed in the display area DA through the link lines LL.

Next, According to an embodiment of the present disclosure, the shielding inspection line ESIL can be an extended portion of the shielding line ESL. Alternatively, the shielding inspection line ESIL can be integrally formed with the shielding line ESL. In this example, the shielding inspection line ESIL can be electrically connected to any one of the inspection parts IP. For example, the shielding inspection line ESIL can extend from the shielding line ESL and can be electrically connected to the first data voltage inspection part DVPa. Thus, as a voltage transmitted from the first data voltage inspection part DVPa is applied to the shielding line ESL, interference due to static electricity between the low power supply voltage contact part VSC and the 1-1st link line LL1a is reduced. Accordingly, interference is reduced due to static electricity generated by a voltage applied to the low power supply voltage contact part VSC in some of the pixels P electrically connected to the first data line DL1 integrally formed with the 1-1 st link line LL1a. Therefore, a problem of fluctuations in threshold voltage Vth of the driving thin film transistor Td disposed in some of the pixels P electrically connected to the first data line DL1 can be minimized or prevented.

Meanwhile, in FIG. 5A, only a state in which the shielding inspection line ESIL is connected to the first data voltage inspection part DVPa is illustrated, but the present disclosure is not limited thereto, and the shielding inspection line ESIL can be electrically connected to any one of the second data voltage inspection part DVPb to the fourth data voltage inspection part DVPd, the reference voltage inspection part REFVP, the high power supply voltage inspection part VDDP, and the low power supply voltage inspection part VSSP. Furthermore, the shielding inspection line ESIL overlaps with any one of the inspection parts disposed in the inspection area IA to secure capacitance capacity, thereby stably performing the inspection.

Next, as shown in FIG. 5B, the display device having completed the inspection process in FIG. 5A can be disconnected or cut so only the display area DA, the first non-display area NDAa, and the second non-display area NDAb remain along a cutting line CL. After removing a partial area of the substrate 100a and the inspection area IA along the cutting line CL, a plurality of pad electrodes PE can be formed at one side of the link lines LL to connect the flexible film (see 320 of FIG. 1). By forming the pad electrodes PE as described above, the display device according to an embodiment of the present disclosure may be implemented.

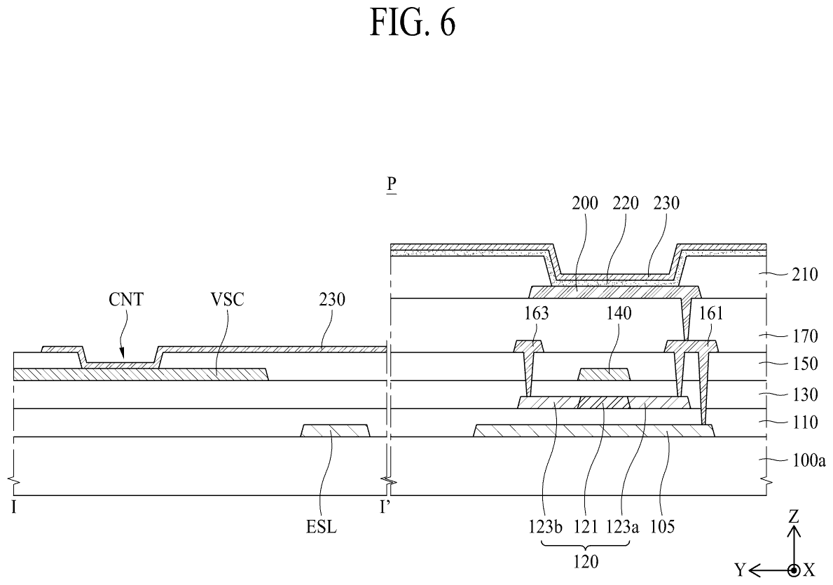

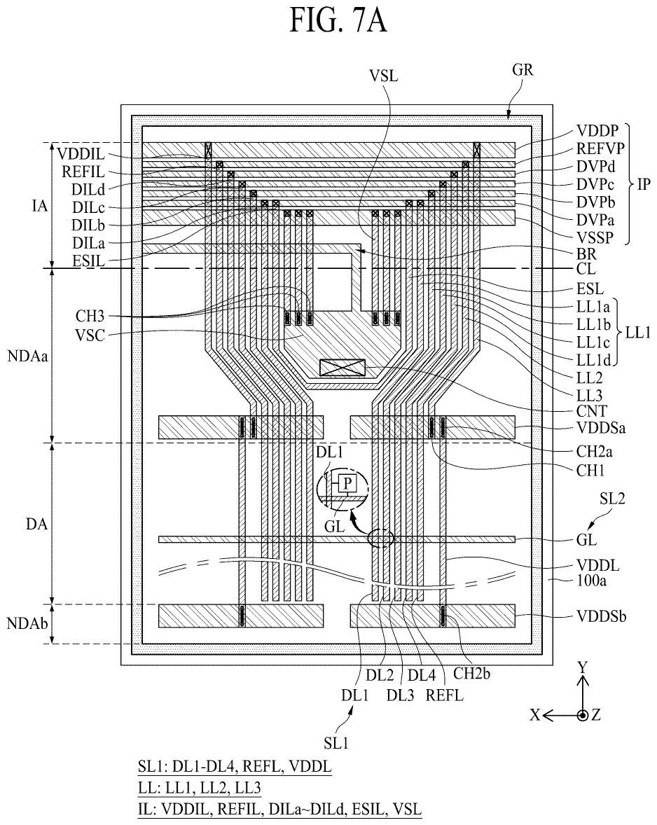

Next, FIG. 6 is a cross-sectional view of a display device according to an embodiment of the present disclosure. In particular, FIG. 6 relates to a cross section I-I′ of FIG. 4 and a cross section of any one pixel and relates to an embodiment of FIGS. 4. 5A and 5B. As shown in FIG. 6, the display device includes a first substrate 100a, a shielding line ESL, a light blocking layer 105, a buffer layer 110, an active layer 120, a gate insulating layer 130, a low power supply voltage contact part VSC, a gate electrode 140, an interlayer insulating layer 150, a source electrode 161, a drain electrode 163, a planarization layer 170, a first electrode 200, a bank 210, a light emitting layer 220, and a second electrode 230.

The first substrate 100a can be made of glass or plastic. In particular, the first substrate 100a can be made of transparent plastic having flexible characteristics, for example, polyimide. When polyimide is used as the first substrate 100a, a heat-resistant polyimide capable of withstanding a high temperature can be used, considering a high temperature deposition process is performed on the first substrate 100a.

In addition, the light blocking layer 105 can be disposed on the first substrate 100a, and can overlap the active layer 120. By forming in this way, light incident from a lower surface of the first substrate 100a can be prevented from flowing into the active layer 120, thereby preventing semiconductor characteristics of the active layer 120, specifically, a channel part 121, from deteriorating.

Also, the shielding line ESL can be disposed on the first substrate 100a, and can be disposed on the same layer using the same material as the light blocking layer 105. Alternatively, the shielding line ESL can be formed on the same layer using the same material as any one of the gate electrode 140, the source electrode 161, and the drain electrode 163 according to the technology level of the art. Further, the shielding line ESL can be formed on the same layer on the gate insulating layer 130 using the same material as the gate electrode 140 and the low power supply voltage contact part VSC. However, the present invention is not limited thereto.

Further, the buffer layer 110 can be disposed on the first substrate 100a. The buffer layer 110 can protect the active layer 120 by blocking air and moisture. The buffer layer 110 can be formed of an inorganic insulating material such as silicon oxide, silicon nitride, or metal oxide, but is not limited thereto and can be formed of an organic insulating material.

Next, the active layer 120 can be disposed on the buffer layer 110. The active layer 120 can include any one of a semiconductor material, for example, amorphous silicon (a-Si), polycrystalline silicon (Poly Si), and an oxide semiconductor material. Also, the active layer 120 can include a channel part 121, a first connection part 123a disposed on one side of the channel part 121, for example, on the right side of the channel part 121, and a second connection part 123b disposed on the other side of the channel part 121, for example, on the left side of the channel part 121.

Also, the channel part 121 can overlap the gate electrode 140 to be protected by the gate electrode 140 in order to maintain semiconductor characteristics without becoming a conductor in a conducting process of making the active layer 120. Also, the first connection part 123a and the second connection part 123b can have conductive characteristics by performing plasma process on a semiconductor material using the gate electrode 140 as a mask or a conductive process of doping ions. Thus, the first connection part 123a and the second connection part 123b formed by the conductive process can have excellent conductive characteristics and can serve as electrodes or wirings.

In addition, the gate insulating layer 130 can be disposed on the active layer 120. The gate insulating layer 130 can be disposed on an entire surface of the first substrate 100a, but is not limited thereto, and can be disposed so one end and the other end of the gate insulating layer 130 correspond to one end and the other end of the gate electrode 140, respectively, by patterning a partial region of the gate insulating layer 130. Also, the gate insulating layer 130 can include a silicon nitride layer (SiNx) or a silicon oxide layer (SiOx), but is not limited thereto. Further, the gate insulating layer 130 can be formed of a single layer or a plurality of layers including an inorganic insulating material and/or an organic insulating material.

Next, the gate electrode 140 can be disposed on the gate insulating layer 130. The gate electrode 140 can include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). Also, the gate electrode 140 can have a structure including one metal layer or a multilayer structure including at least two metal layers each having different physical properties.

Next, the low power supply voltage contact part VSC can be disposed on the gate insulating layer 130. For example, the low power supply voltage contact part VSC can be formed on the same layer using the same material as the gate electrode 140, but is not limited thereto, and can be disposed at various positions according to the technical level of the art. For example, the low power supply voltage contact part VSC can be formed, as another example, on the same layer using the same material as the light blocking layer 105, the source electrode 161, or the drain electrode 163.

Further, the interlayer insulating layer 150 can be disposed on the gate electrode 140 to insulate the gate electrode 140 from the source electrode 161, and further insulate the gate electrode 140 from the drain electrode 163. Also, the interlayer insulating layer 150 can be formed of a single layer or a plurality of layers including an inorganic insulating material and/or an organic insulating material. Further, a contact hole can be disposed in the interlayer insulating layer 150. Accordingly, a portion of an upper surface of the first connection part 123a of the active layer 120 can be exposed by any one contact hole, and further, a portion of an upper surface of the second connection part 123b of the active layer 120 can be exposed by another contact hole.

In addition, a contact part CNT can be disposed in the interlayer insulating layer 150 to electrically connect the low power supply voltage contact part VSC and the second electrode 230. Also, as the contact part CNT is disposed in the interlayer insulating layer 150, a portion of an upper surface of the low power supply voltage contact part VSC can be exposed, thereby electrically connecting the low power supply voltage contact part VSC and the second electrode 230.

Next, the source electrode 161 and the drain electrode 163 can be disposed on the interlayer insulating layer 150. Also, the source electrode 161 can be electrically connected to the first connection part 123a of the active layer 120 by a contact hole, and the drain electrode 163 can be electrically connected to the second connection part 123b of the active layer 120 by a contact hole. Further, the source electrode 161 and the drain electrode 163 can be formed of the same material as the gate electrode 140, but are not limited thereto and can be formed of a material according to knowledge in the art.

Then, the planarization layer 170 can be disposed on the interlayer insulating layer 150, the source electrode 161, and the drain electrode 163. Also, the planarization layer 170 can be disposed on the source electrode 161 and the drain electrode 163 to planarize an upper surface of the planarization layer 170. Further, a contact hole can be disposed in the planarization layer 170, and a portion of an upper surface of the source electrode 161 can be exposed by the contact hole. However, in some examples, a portion of an upper surface of the drain electrode 163 can be exposed by the contact hole. Also, the planarization layer 170 can be formed of an organic insulating layer material. For example, the planarization layer 170 can be formed of an organic insulating material such as an acrylic resin, an epoxy resin, a phenolic resin, a polyamide resin, or a polyimide resin.

Further, the first electrode 200, which can function as an anode electrode, can be disposed on the planarization layer 170, and can be electrically connected to the source electrode 161 through a contact hole disposed in the planarization layer 170. The first electrode 200 can be patterned on the planarization layer 170 and patterned to correspond to the subpixels (e.g., subpixels SP1 to SP4 that may be included in the pixel P of FIG. 3). Therefore, for example, the first electrode 200 can be patterned to correspond to the first subpixel SP1 and the second subpixel SP2.

In addition, the bank 210 can be disposed on the first electrode 200. In this example, a partial area of an upper surface of the first electrode 200 exposed without being covered by the bank 210 forms a light emitting area. In varying examples, the bank 210 can be formed of an organic film such as an acrylic resin, an epoxy resin, a phenolic resin, a polyamide resin, or a polyimide resin.

Further, the light emitting layer 220 can be disposed on the first electrode 200. In varying examples, the light emitting layer 220 can include red, green, and blue emission layers patterned for each sub-pixel, or can be formed of a white emission layer connected to all pixels. When the light emitting layer 220 is formed of a white emission layer, the light emitting layer 220 can include, for example, a first stack including a blue emission layer, a second stack including a yellow-green emission layer, and a charge generation layer disposed between the first stack and the second stack, but is not limited thereto.

Also, the second electrode 230, which can function as a cathode electrode, can be disposed on the light emitting layer 220. In varying examples, an encapsulation layer can be disposed on the second electrode 230 to prevent moisture or air from entering the light emitting layer 220 from an outside of the display device.

As a variant of FIGS. 4-6, an additional conductor can be formed directly above the shielding line ESL on the top surface of buffer layer 110 and formed of the same semiconductor material as the active layer 120 while being made conductive using the same process applied to the first connection part 123a and the second connection part 123b. As another variant of FIGS. 4-6, an additional conductor can be formed directly above the shielding line ESL on the top surface of gate insulating layer 130 and formed of the same material as gate electrode 140. In both variants the additional conductive layer can be shorted to the shielding line ESL using one of more through-holes in buffer layer 110 and/or gate insulating layer 130.

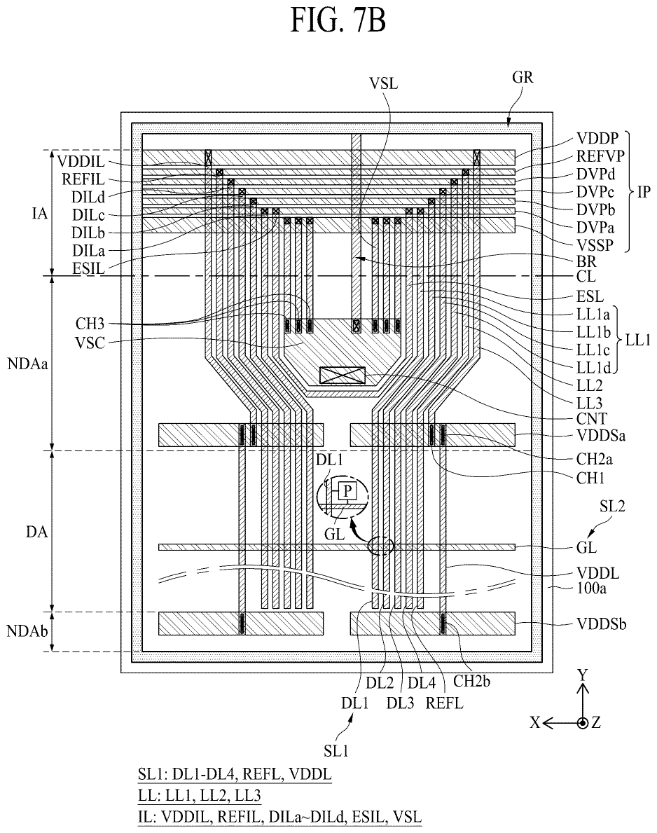

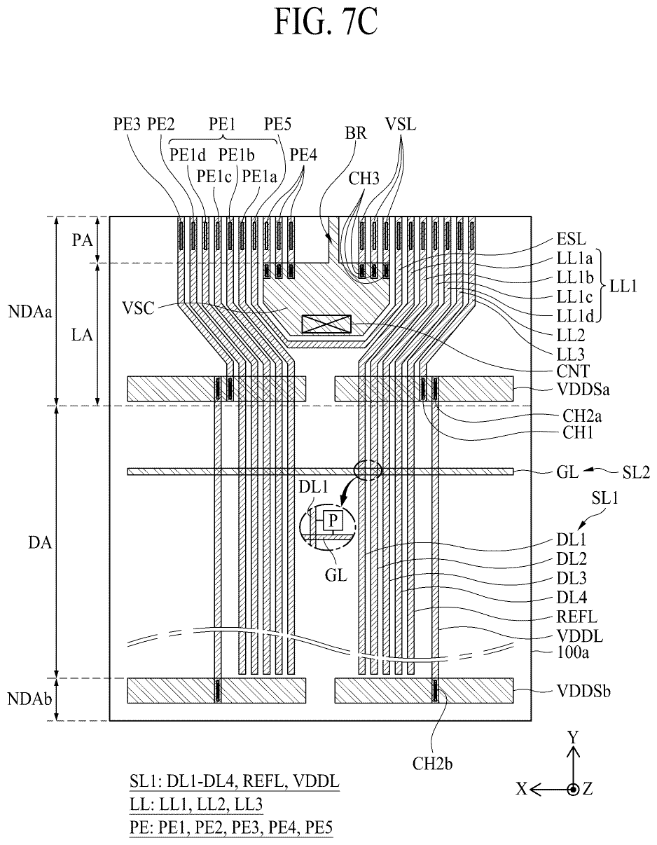

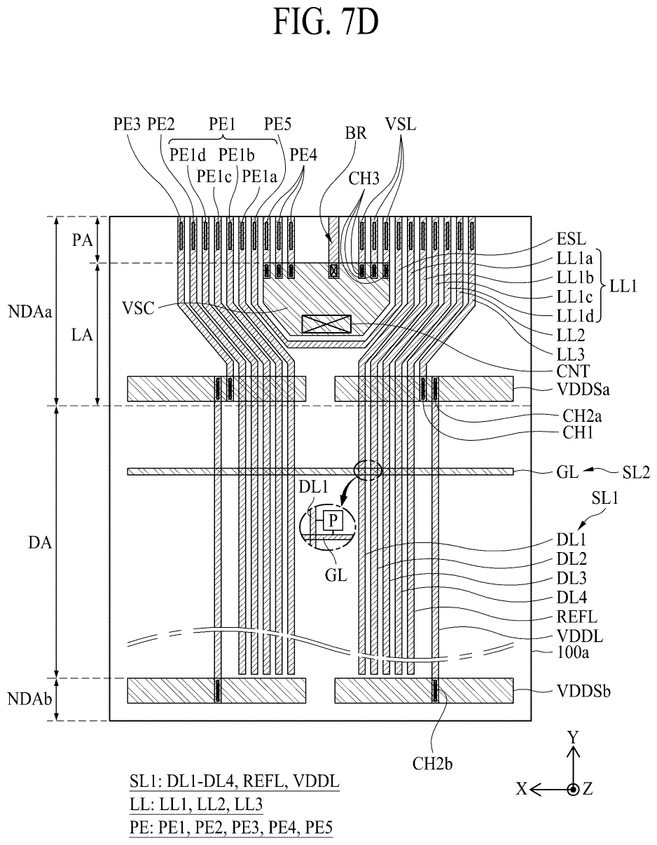

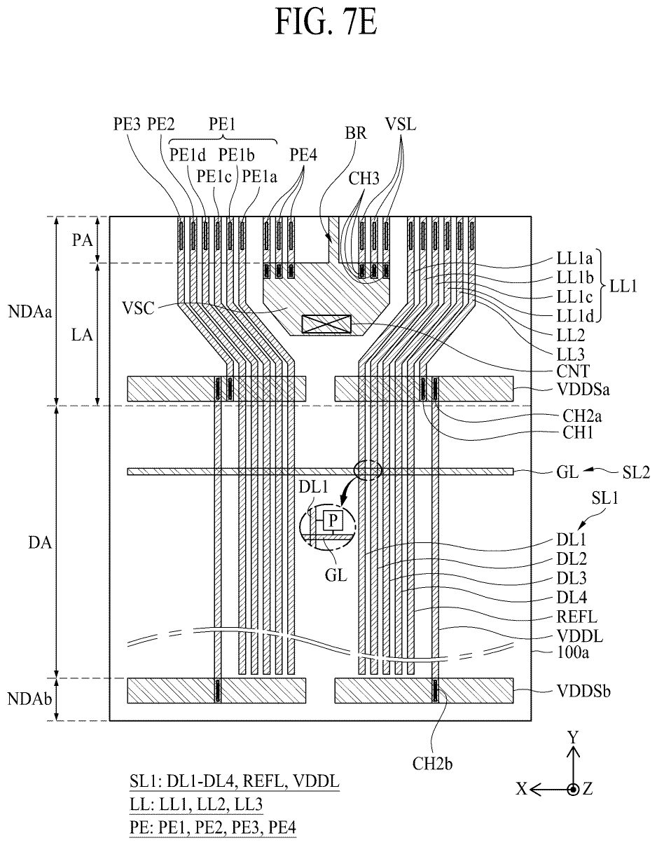

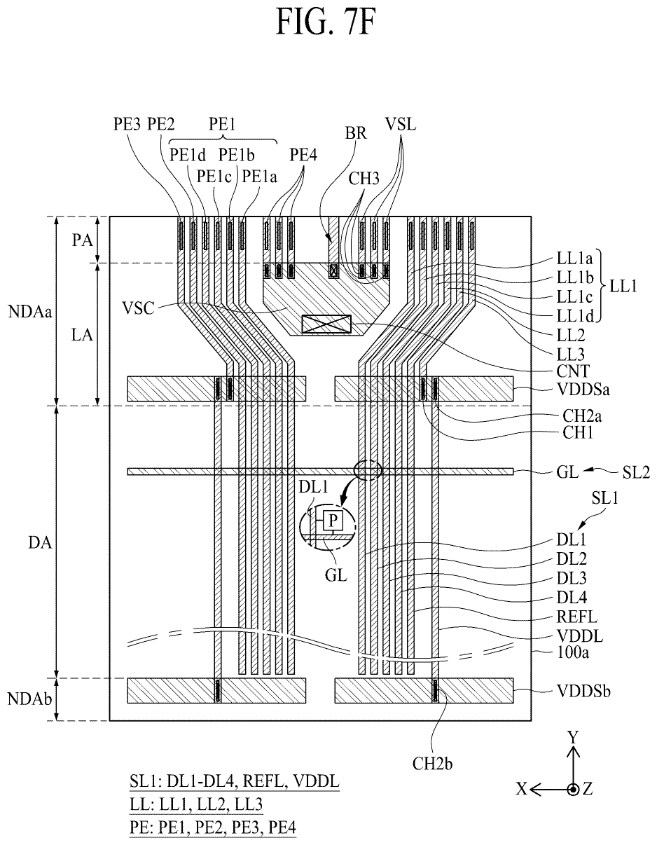

Next, FIGS. 7A and 7B are plan views of a display device before a cutting process according to an embodiment, and FIGS. 7C and 7D are plan views of a display device after the cutting process according to an embodiment. Hereinafter, a configuration different from an embodiment of FIGS. 5A and 5B will be mainly described. First, as shown in FIGS. 7A and 7B, in order to manufacture a display device according to an embodiment, a plurality of link lines LL, a low power supply voltage contact part VSC, a shielding line ESL, a first high power supply voltage shorting bar VDDSa, a second high power supply voltage shorting bar VDDSb, a plurality of first signal lines SL1, a plurality of second signal lines SL2, and a plurality of pixels P can be formed on the first substrate 100a. In the example of FIGS. 7A and 7B, a guide ring GR surrounding an outer surface of the first substrate 100a can be additionally disposed. For example, the guide ring GR may be provided on the first substrate 100a along the outer circumference of the first substrate 100a.

Also, the guide ring GR can connect an all of plurality of link lines LL, the low power supply voltage contact part VSC, the shielding line ESL, the first high power supply voltage shorting bar VDDSa, the second high power supply voltage shorting bar VDDSb, the first signal lines SL1, and the second signal lines SL2 to an equipotential, thereby reducing a problem in which static electricity flows into the a thin film transistor in each pixel. Further, a first data voltage inspection line DILa to a fourth data voltage inspection line DILd extend to the guide ring GR and are electrically connected to the guide ring GR, so the link lines LL, data lines DL1, DL2, DL3 DL4 constituting the first signal lines SL1, and the shielding line ESL can be electrically connected to the guide ring GR.

In addition, since a reference voltage inspection part REFVP extends to the guide ring GR and is electrically connected to the guide ring GR, a reference line REFL constituting the first signal lines SL1 can be electrically connected to the guide ring GR. In addition, the high power supply voltage inspection line VDDIL extends to the guide ring GR and is electrically connected to the guide ring GR, so the first and second high power supply voltage shorting bars VDDSa and VDDSb and a high power supply voltage line VDDL constituting the first signal lines SL1 can be electrically connected to the guide ring GR.

Furthermore, the second signal lines SL2 can be directly connected to the guide ring GR, connected to the guide ring GR through a contact hole, or electrically connected to the guide ring GR through a separate transistor. In addition, a low power supply voltage inspection part VSSP can extend to the guide ring GR to electrically connect the low power supply voltage contact part VSC to the guide ring GR, but the low power supply voltage inspection part VSSP may not extend to the guide ring GR so that the low power supply voltage contact part VSC may not be electrically connected to the guide ring GR.

According to an embodiment, the low power supply voltage contact part VSC and the guide ring GR can be connected through a separate bridge line BR. Also, the bridge line BR can connect the low power supply voltage contact part VSC and the guide ring GR through various paths. For example, as shown in FIG. 7A, the bridge line BR can be connected to a left portion of the guide ring GR while crossing the link lines LL, the shielding line ESL, and the low power supply voltage line VSL by extending upward from the low power supply voltage contact part VSC and then to the left. In this example, the bridge line BR can be disposed on a layer different from the link lines LL, the shielding line ESL, and the low power supply voltage line VSL.

Further, in some examples, the bridge line BR can be connected to a lower left portion of the guide ring GR by crossing the link lines LL, the shielding line ESL, and the low power supply voltage line VSL, extending downward and then extending back to the left. The bridge line BR can also be formed of the same material in the same layer as the low power supply voltage contact part VSC, but is not limited thereto, and can be formed of a different material in a layer different from the low power supply voltage contact part VSC and connected to the low power supply voltage contact part VSC through a contact hole.

As another example, as shown in FIG. 7B, the bridge line BR can extend upward from the low power supply voltage contact part VSC and can cross the data voltage inspection line DILa to DILd, the reference voltage inspection part REFVP, and the high power supply voltage inspection line VDDIL to be connected to an upper portion of the guide ring GR, and in this example, the bridge line BR can be formed on the same layer as any one of the link lines LL, the shielding line ESL, and the low power supply voltage line VSL, but is not limited thereto. Also, the bridge line BR can be made of a material different from a material of the low power supply voltage contact part VSC in a layer different from a layer of the low power supply voltage contact part VSC, and can be connected to the low power supply voltage contact part VSC through a contact hole, but is not limited thereto.

In some examples, the bridge line BR includes a first portion and a second portion. Further, the first portion can be a lower portion of the bridge line BR not intersecting the data voltage inspection lines DILa to DILd, the reference voltage inspection part REFVP, the high power supply voltage inspection line VDDIL. Still further, the second portion can be an upper portion of the bridge line BR intersecting the data voltage inspection lines DILa to DILd, the reference voltage inspection unit REFVP, the high power supply voltage inspection line VDDIL. In addition, the first portion and the second portion can be formed on different layers. In addition, when the low power supply voltage inspection part VSSP extends to the guide ring GR above and the low power supply voltage contact part VSC is electrically connected to the guide ring GR, the bridge line BR can be electrically connected to the guide ring GR through the low power supply voltage inspection part VSSP by being connected to the low power supply voltage inspection part VSSP.

Next, as shown in FIG. 7C, the display device having completed the inspection step in FIG. 7A can be cut along the cutting line CL so only the display area DA, the first non-display area NDAa, and the second non-display area NDAb remain. In addition, as shown in FIG. 7D, the display device having completed the inspection step in FIG. 7B can be cut along the cutting line CL so only the display area DA, the first non-display area NDAa, and the second non-display area NDAb remain.

As shown in FIGS. 7C and 7D, after a partial area of the substrate 100a and the inspection area IA are removed along the cutting line CL, a portion of the first substrate 100a can be disconnected or cut in order to remove the remaining portion of the guide ring GR. Thereafter, a plurality of pad electrodes PE can be formed at one side of the link lines LL to be connected to the flexible film (see 320 of FIG. 1). By removing the guide ring GR and forming the pad electrodes PE in this way, the display device according to an embodiment of the present invention can be implemented. In this example, the bridge line BR extends in one direction from the low power supply voltage contact part VSC, for example, upward. Also, one end of the bridge line BR can be connected to the low power supply voltage contact part VSC, and the other end of the bridge line BR can coincide with an end of the substrate 100a.

In addition, since external signals must be applied to lines such as the shielding line ESL, the link line LL, and the low power supply voltage line VSL, the lines are connected to the pad electrodes PE1, PE2, PE3, PE4, and PE5. In particular, a fourth pad electrode PE4 is connected to the low power supply voltage line VSL in order to supply the low power supply voltage applied from an outside to the low power supply voltage contact part VSC. Therefore, the low power supply voltage applied from the outside can be transferred to the low power supply voltage line VSL through the fourth pad electrode PE4 and then supplied to the low power supply voltage contact part VSC through a third contact hole CH3. As an external signal need not be applied to the bridge line BR, the bridge line BR can be connected to the low power supply voltage contact part VSC directly or through a contact hole, but a separate pad electrode is not connected to the bridge line BR. In this way, the low power supply voltage line VSL and the bridge line BR can be disposed parallel to each other in the same direction, for example, in the upward direction, in the low power supply voltage contact part VSC. In addition, one end of each of the low power supply voltage line VSL and the bridge line BR is connected to the low power supply voltage contact part VSC, and the other end of each of the low power supply voltage line VSL and the bridge line BR coincides with one end of the substrate 100a, for example, an upper end of the substrate 100a.

In this example, the fourth pad electrode PE4 is connected to the other end area of the low power supply voltage line VSL, while the pad electrode is not connected to the other end area of the bridge line BR. For example, the low power supply voltage line VSL and the bridge line BR can be formed on different layers as shown in FIG. 7C, or can be formed of the same material in the same layer as shown in FIG. 7D. In other words, as shown in FIG. 7C, the low power supply voltage line VSL is connected to the low power supply voltage contact part VSC through a third contact hole CH3, and the bridge line BR can be integrally formed with the low power supply voltage contact part VSC and, as shown in FIG. 7D, the low power supply voltage line VSL can be connected to the low power supply voltage contact part VSC through a third contact hole CH3, and the bridge line BR can also be connected to the low power supply voltage contact part VSC through a contact hole.

Next, FIGS. 7E and 7F are plan views of a display device according to another embodiment of the present disclosure. FIG. 7E illustrates the shielding line ESL and the fifth pad electrode PE5 being excluded from FIG. 7C, and FIG. 7F illustrates the shielding line ESL and the fifth pad electrode PE5 being excluded from FIG. 7D. As shown in FIGS. 7E and 7F, static electricity in the low power supply voltage contact part VSC can be removed through the bridge line BR connected to the guide ring GR without configuring the shielding line ESL.

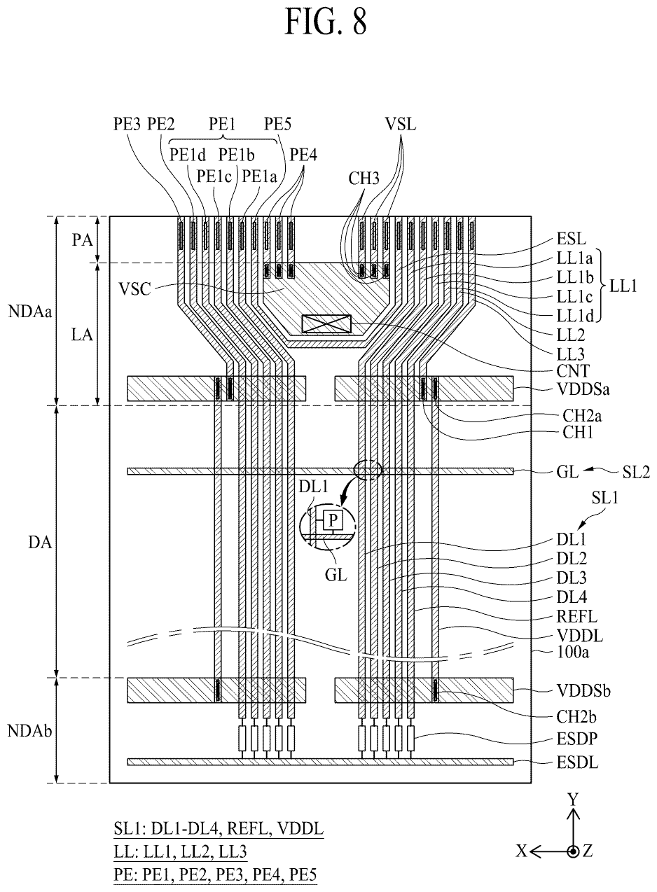

Next, FIG. 8 is a plan view of a display device according to another embodiment of the present disclosure. Meanwhile, the embodiment of FIG. 8 is similar to the embodiment of FIG. 4 except for a configuration of an electrostatic discharge pattern, and thus different configurations will be mainly described below. As shown in FIG. 8, a display device according to another embodiment of the present disclosure includes a first substrate 100a, a plurality of pad electrodes PE, a plurality of link lines LL, a low power supply voltage contact part VSC, a shielding line ESL, a first high power supply voltage shorting bar VDDSa, a second high power supply voltage shorting bar VDDSb, a plurality of first signal lines SL1, a plurality of second signal lines SL2, an electrostatic discharge pattern ESDP, and an electrostatic discharge signal line ESDL.

According to another embodiment of the present disclosure, the second non-display area NDAb can further include the electrostatic discharge pattern ESDP and the electrostatic discharge signal line ESDL. The electrostatic discharge pattern ESDP can be connected to one end, for example, a lower end of the first signal lines SL1. For example, the electrostatic discharge pattern ESDP can be electrically connected to any one end of the first data line DL1, the second data line DL2, the third data line DL3, the fourth data line DL4, and the reference line REFL. Also, the electrostatic discharge pattern ESDP can be electrically connected to the electrostatic discharge signal line ESDL. Further, the electrostatic discharge pattern ESDP can be disposed between a portion of the first signal lines SL1 and the electrostatic discharge signal line ESDL, thereby preventing static electricity from being generated in the pixels P. Still further, FIG. 8 shows only the electrostatic discharge pattern ESDP disposed in the second non-display area NDAb, but the present disclosure is not limited thereto, and the electrostatic discharge pattern ESDP can be disposed in the display area DA, and can be disposed in various arrangements according to common sense in the art. The electrostatic discharge signal line ESDL can extend in a first direction X, for example, a horizontal direction, and can receive a predetermined voltage.

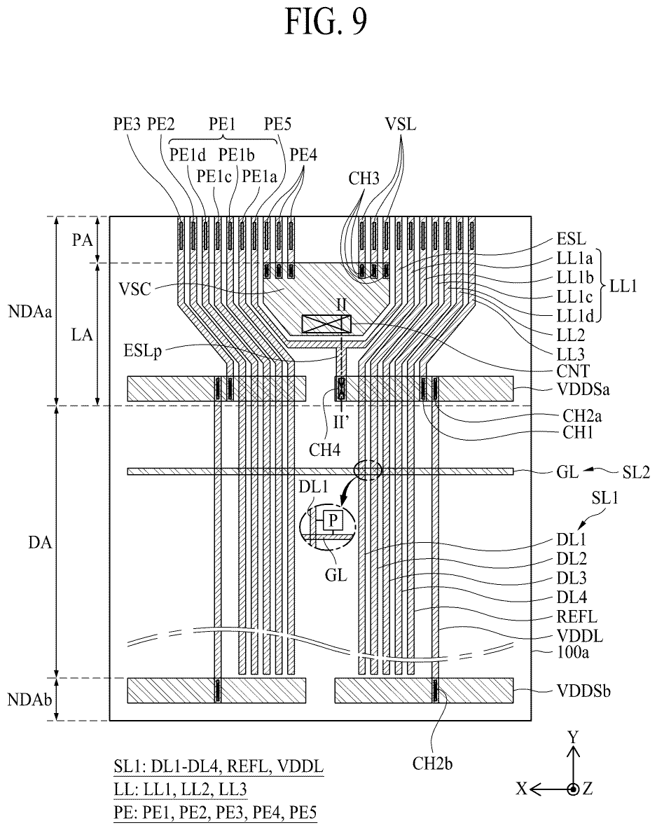

Next, FIG. 9 is a plan view of a display device according to another embodiment of the present disclosure. In particular, the embodiment of FIG. 9 is similar to the embodiment of FIG. 4 except for a configuration of the shielding line, and thus different configurations will be mainly described below. As shown in FIG. 9, a display device according to another embodiment of the present disclosure includes a first substrate 100a, a plurality of pad electrodes PE, a plurality of link lines LL, a low power supply voltage contact part VSC, a shielding line ESL, a first high power supply voltage shorting bar VDDSa, a second high power supply voltage shorting bar VDDSb, a plurality of first signal lines SL1, a plurality of second signal lines SL2, and a plurality of pixels P.

According to yet another embodiment, unlike the embodiment of FIG. 4, the flexible film (see 320 of FIG. 1) may not be electrically connected to the fourth pad electrode PE4 for applying a signal to the shielding line ESL. According to another embodiment of the present disclosure, the shielding line ESL includes a protrusion ESLp protruding one side, for example, downward and extending. Further, the protrusion ESLp can be electrically connected to the first high power supply voltage shorting bar VDDSa through a fourth contact hole CH4. Accordingly, the shielding line ESL can be applied with a high power supply voltage through the first high power supply voltage shorting bar VDDSa. By forming in this way, the shielding line ESL can be disposed between the low power supply voltage contact part VSC and the 1-1st link line LL1a in a state in which the shielding line ESL is not floated.

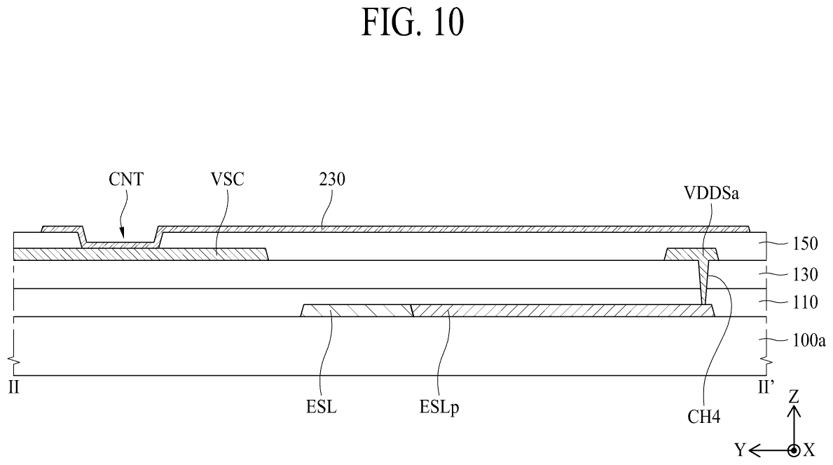

Next, FIG. 10 is a cross-sectional view of a display device according to another embodiment of the present disclosure. In particular, FIG. 10 relates to a cross section II-II′ of FIG. 9 configuration, and repeated descriptions are omitted. As shown in FIG. 10, a display device according to another embodiment of the present disclosure includes a first substrate 100a, a shielding line ESL, a protrusion ESLp, a buffer layer 110, a gate insulating layer 130, a low power supply voltage contact part VSC, a first high power supply voltage shorting bar VDDSa, an interlayer insulating layer 150, and a second electrode 230. The shielding line ESL can be electrically connected to the first high power supply voltage shorting bar VDDSa through the protrusion ESLp which protrudes and extends in the second direction Y. In this example, the first high power supply voltage shorting bar VDDSa and the shielding line ESL can be electrically connected to each other through a fourth contact hole CH4. According to another embodiment of the present disclosure, the shielding line ESL can be electrically connected to the first high power supply voltage shorting bar VDDSa through the protrusion ESLp to receive a predetermined voltage without being floated. Accordingly, interference due to static electricity between the low power supply voltage contact part VSC and the 1-1st link line (see LL1a of FIG. 4) can be prevented.

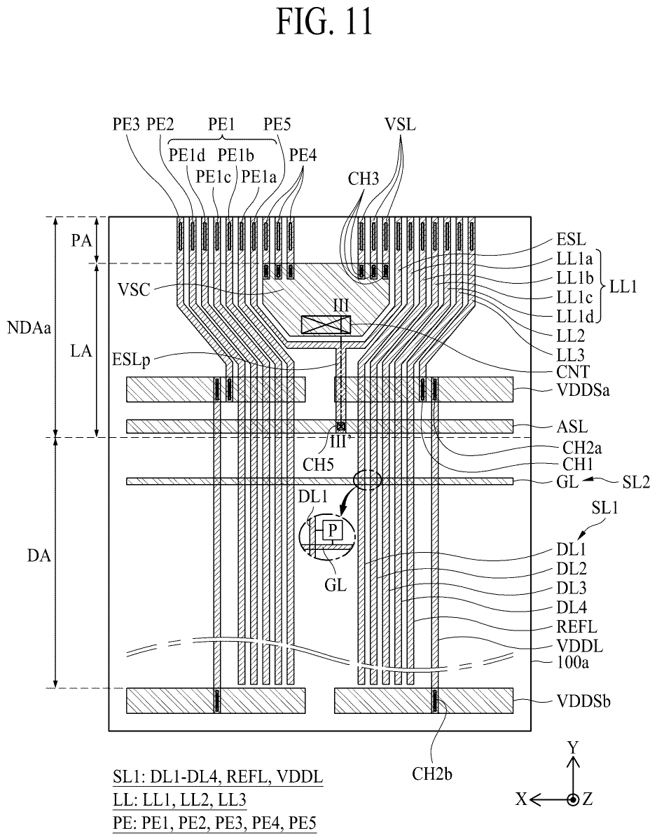

Next, FIG. 11 is a plan view of a display device according to another embodiment of the present disclosure. In particular, FIG. 11 is similar to the embodiment of FIG. 4 except for a configuration of a shielding line and an additional horizontal line, different configurations will be mainly described below. As shown in FIG. 11, the display device includes a first substrate 100a, a plurality of pad electrodes PE, a plurality of link lines LL, a low power supply voltage contact part VSC, a shielding line ESL, a first high power supply voltage shorting bar VDDSa, a second high power supply voltage shorting bar VDDSb, an additional horizontal line ASL, a plurality of first signal lines SL1, a plurality of second signal lines SL2, and a plurality of pixels P. Also, the additional horizontal line ASL can be disposed in the first non-display area NDAa. For example, the additional horizontal line ASL can be disposed in the first non-display area NDAa to be relatively adjacent to the display area DA than the first high power supply voltage shorting bar VDDSa. In operation, additional horizontal line ASL can receive any one of a low power supply voltage applied to the low power supply voltage contact part VSC, a ground voltage, and a signal flowing through another line disposed in the first non-display area NDAa. Unlike the embodiment of FIG. 4, in an embodiment of FIG. 11, the flexible film (see 320 of FIG. 1) may not be electrically connected to the fourth pad electrode PE4 for applying a signal to the shielding line ESL.

According to another embodiment of the present disclosure, the shielding line ESL includes a protrusion ESLp protruding one side, for example, downward and extending. The protrusion ESLp can be electrically connected to the additional horizontal line ASL through a fifth contact hole CH5. Accordingly, the shielding line ESL can receive any one of a low power supply voltage, a ground voltage, and a signal flowing to another line disposed in the first non-display area NDAa. By forming in this way, the shielding line ESL can be disposed between the low power supply voltage contact part VSC and the 1-1st link line LL1a in a state in which the shielding line ESL is not floated.

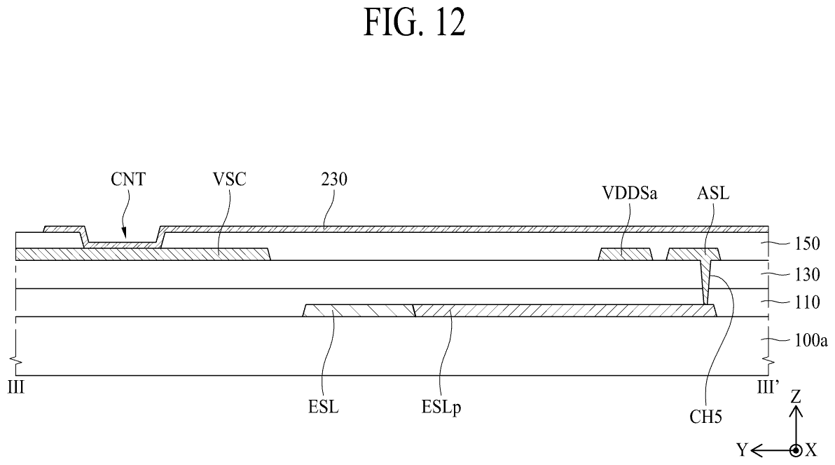

Next, FIG. 12 is a cross-sectional view of a display device relating to a cross section III-III′ of FIG. 11. As shown in FIG. 12, the display device includes a first substrate 100a, a shielding line ESL, a protrusion ESLp, a buffer layer 110, a gate insulating layer 130, a low power supply voltage contact part VSC, a first high power supply voltage shorting bar VDDSa, an additional horizontal line ASL, an interlayer insulating layer 150, and a second electrode 230. Also, the shielding line ESL can be electrically connected to the additional horizontal line ASL through the protrusion ESLp protruding and extending in the second direction Y. In this example, the additional horizontal line ASL and the shielding line ESL can be electrically connected through a fifth contact hole CH5. Also, the shielding line ESL can be electrically connected to the additional horizontal line ASL through the protrusion ESLp to receive a predetermined voltage without being floated. Accordingly, interference due to static electricity between the low power supply voltage contact part VSC and the 1-1st link line (see LL1a of FIG. 4) can be prevented.

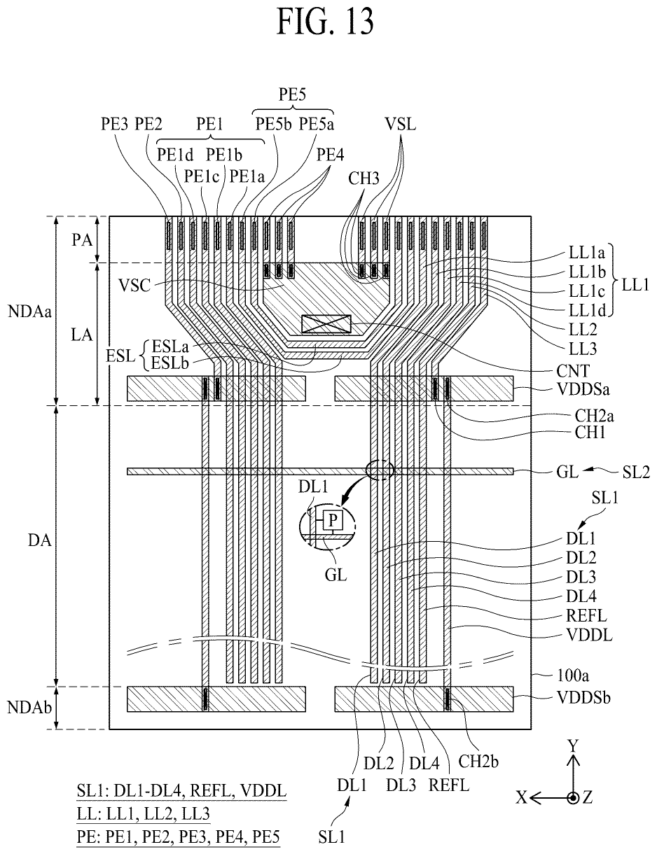

Next, FIG. 13 is a plan view of a display device according to another embodiment, and is similar to the embodiment of FIG. 4 except for a configuration of the shielding line, and thus different configurations will be mainly described below. As shown in FIG. 13, the example display device includes a first substrate 100a, a plurality of pad electrodes PE, a plurality of link lines LL, a low power supply voltage contact part VSC, a first shielding line ESLa, a second shielding line ESLb, a first high power supply voltage shorting bar VDDSa, a second high power supply voltage shorting bar VDDSb, a plurality of first signal lines SL1, a plurality of second signal lines SL2, and a plurality of pixels P. Also, the first shielding line ESLa and the second shielding line ESLb can be disposed between the link lines LL and the low power supply voltage contact part VSC. By forming the shielding line ESL (including the first shielding line ESLa and the second shielding line ESLb) between the link lines LL and the low power supply voltage contact part VSC, it is possible to minimize a voltage applied to the low power supply voltage contact part VSC in an inspection process from affecting the link lines LL. For example, the inspection process can be checking whether a signal such as a data voltage is normally applied to the first signal lines SL1 or checking whether a low power supply voltage is normally applied to the low power supply voltage contact part VSC, but is not limited thereto.

Also, when a voltage is applied to the low power supply voltage contact part VSC, a threshold voltage Vth of the driving thin film transistor TRd of the pixel connected to the first link line LL1 and the first data line DL1 disposed closest to the low power supply voltage contact part VSC can be varied. However, according to another embodiment of the present disclosure, the influence of the voltage applied to the low power supply voltage contact part VSC on the link lines LL in the inspection process can be minimized or removed by the first shielding line ESLa and the second shielding line ESLb. While the example of FIG. 13 illustrates only two shielding lines between the link lines LL and the low power supply voltage contact part VSC, in other examples the shielding lines can be adjusted in various numbers according to the performance of the display device to be implemented. Thus, by providing the first shielding line ESLa and the second shielding line ESLb, fluctuations in the threshold voltage Vth of the driving thin film transistors disposed in the pixels disposed in the display device can be minimized. Accordingly, it is possible to minimize or prevent an occurrence of stains or lines when an image is displayed or reproduced.

Also, the first shielding line ESLa and the second shielding line ESLb can surround an outer side of the low power supply voltage contact part VSC within the link area LA. Further, an inside of the low power supply voltage contact part VSC can be defined as an inside where a contact part CNT is formed based on a boundary of the low power supply voltage contact part VSC, and an outside of the low power supply voltage contact part VSC can be defined as an outside of the boundary of the low power supply voltage contact part VSC where the contact part CNT is not formed. Compared with the first shielding line ESLa, the second shielding line ESLb can be relatively spaced apart from the low power supply voltage contact part VSC in an outward direction. Therefore, the first shielding line ESLa can surround the low power supply voltage contact part VSC, and the second shielding line ESLb can surround the low power supply voltage contact part VSC or the first shielding line ESLa. Also, different voltages can be applied to the first shielding line ESLa and the second shielding line ESLb. For example, a 1-1st voltage can be applied to the first shielding line ESLa through a 5-1st pad electrode PE5a, and a 1-2nd voltage can be applied to the second shielding line ESLb through the 5-2nd pad electrode PE5b. In this example, different voltages can be applied to the 1-1st voltage and the 1-2nd voltage. As yet another example, the 5-1st pad electrode PE5a connected to the first shielding line ESLa can be maintained in a floating state without being electrically connected to the flexible film (see 320 of FIG. 1), and the 1-2nd voltage can be applied only to the second shielding line ESLb so as not to be floated.

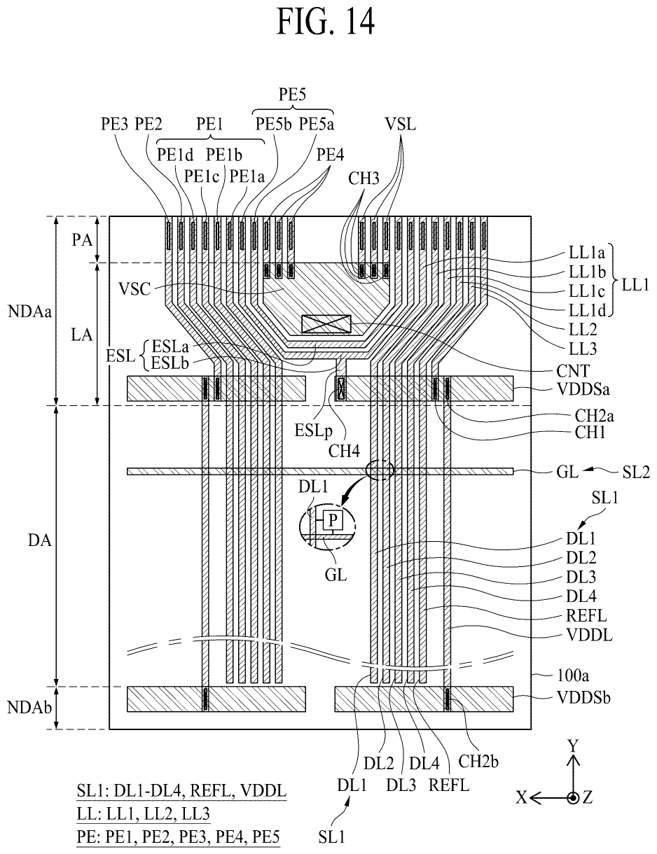

Next, FIG. 14 is a plan view of a display device according to another embodiment of the present disclosure. In particular, the embodiment of FIG. 14 is similar to the embodiment of FIG. 13 except for a configuration of the second shielding line, and thus different configurations will be mainly described below. As shown, the display device according to FIG. 14 includes a first substrate 100a, a plurality of pad electrodes PE, a plurality of link lines LL, a low power supply voltage contact part VSC, a first shielding line ESLa, a second shielding line ESLb, a first high power supply voltage shorting bar VDDSa, a second high power supply voltage shorting bar VDDSb, a plurality of first signal lines SL1, a plurality of second signal lines SL2, and a plurality of pixels P. Unlike the embodiment of FIG. 13, the flexible film (see 320 of FIG. 1) may not be electrically connected to the 5-2nd pad electrode PE5b for applying a signal to the second shielding line ESLb. Also, the second shielding line ESLb includes a protrusion ESLp protruding one side, for example, downward and extending, and can be electrically connected to the first high power supply voltage shorting bar VDDSa through a fourth contact hole CH4. Accordingly, the second shielding line ESLb can be applied with a high power supply voltage through the first high power supply voltage shorting bar VDDSa. By forming in this way, the second shielding line ESLb can be disposed between the low power supply voltage contact part VSC and the 1-1st link line LL1a in a state in which the second shielding line ESLb is not floated.

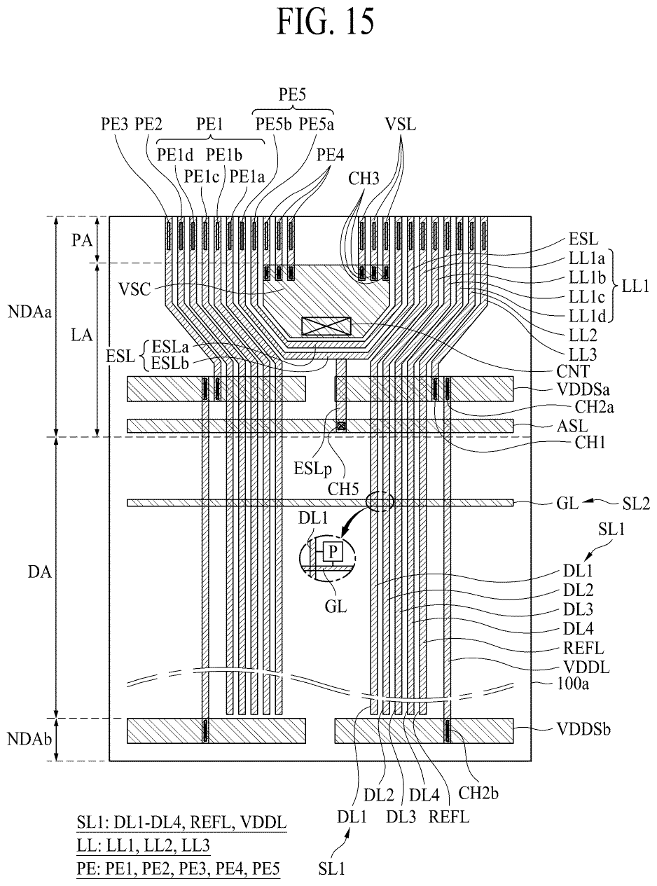

Next, FIG. 15 is a plan view of a display device according to another embodiment of the present disclosure. The embodiment of FIG. 15 is similar to the embodiment of FIG. 13 except for a configuration of the second shielding line and the additional horizontal line, different configurations will be mainly described below. As shown in FIG. 15, the example display device includes a first substrate 100a, a plurality of pad electrodes PE, a plurality of link lines LL, a low power supply voltage contact part VSC, a shielding line ESL, a first high power supply voltage shorting bar VDDSa, a second high power supply voltage shorting bar VDDSb, an additional horizontal line ASL, a plurality of first signal lines SL1, a plurality of second signal lines SL2, and a plurality of light-emitting pixels P.

Also, the additional horizontal line ASL can be disposed in the first non-display area NDAa. For example, the additional horizontal line ASL can be disposed in the first non-display area NDAa to be relatively adjacent to the display area DA than the first high power supply voltage shorting bar VDDSa. In operation, the additional horizontal line ASL can receive any one of a low power supply voltage applied to the low power supply voltage contact part VSC, a ground voltage, and a signal flowing through another line disposed in the first non-display area NDAa. Unlike the embodiment of FIG. 13, in the of FIG. 15, the flexible film (see 320 of FIG. 1) may not be electrically connected to the 5-2nd pad electrode PE5b for applying a signal to the second shielding line ESLb. Also, the second shielding line ESLb includes a protrusion ESLp protruding one side, for example, downward and extending, and can be electrically connected to the additional horizontal line ASL through a fifth contact hole CH5. Accordingly, the second shielding line ESLb can receive any one of the low power supply voltage, the ground voltage, and the signal flowing through another line disposed in the first non-display area NDAa. By being formed as described above, the second shielding line ESLb can be disposed between the low power supply voltage contact part VSC and the 1-1st link line LL1a in a state in which the second shielding line ESLb is not floated.

The present disclosure described above is not limited by the above-described embodiments and the accompanying drawings and various substitutions, modifications and variations can be made in the present disclosure without departing from the spirit or scope of the disclosures. Consequently, the scope of the present disclosure is defined by the accompanying claims and it is intended for all variations or modifications derived from the meaning, scope and equivalent concept of the claims to fall within the scope of the present disclosure.

What is claimed is:

1. A display device comprising:
a substrate including a display area having light emitting pixels and including a non-display area;
a plurality of first signal lines in the display area connected to the light emitting pixels;
a plurality of second signal lines connected to the light emitting pixels, disposed in the display area, and extending in a direction perpendicular to the plurality of first signal lines;
a plurality of pad electrodes in the non-display area;
a plurality of link lines disposed in the non-display area and electrically connecting respective pad electrodes and first signal lines;
a low power supply voltage contact part in the non-display area spaced apart from plurality of link lines in plan view;
an electrode covering the low power supply voltage contact part electrically connecting the low power supply voltage contact part to cathode electrodes of the light emitting pixels; and
a shielding line disposed between the plurality of link lines and the low power supply voltage contact part and shielding an influence of a voltage applied to the low power supply voltage contact part.

2. The display device of claim 1, wherein the shielding line surrounds an outer side of the low power supply voltage contact part.

3. The display device of claim 1, further comprising:
a high power supply voltage shorting bar overlapping the plurality of link lines and electrically connected to a high power supply voltage line,
wherein the shielding line includes a protrusion protruding to and electrically connected to the high power supply voltage shorting bar.

4. The display device of claim 1, further comprising:
a horizontal signal line overlapping the plurality of link lines and extending in a direction parallel to the plurality of second signal lines,
wherein the shielding line includes a protrusion protruding and electrically connected to the horizontal signal line.

5. The display device of claim 4, wherein the horizontal signal line receives a signal from either a ground voltage or a low power supply voltage.

6. The display device of claim 1, wherein the shielding line includes a first shielding line disposed adjacent to the low power supply voltage contact part and a second shielding line disposed adjacent to the plurality of link lines, and
wherein the first shielding line surrounds an outer side of the low power supply voltage contact part, and the second shielding line surrounds an outer side of the first shielding line.

7. The display device of claim 6, wherein the first shielding line and the second shielding line are electrically connected to different pad electrodes among the plurality of pad electrodes.

8. The display device of claim 6, wherein the first shielding line is floated, and the second shielding line receives a signal from a pad electrode of the plurality of pad electrodes.

9. The display device of claim 6, further comprising:
a high power supply voltage shorting bar overlapping the plurality of link lines and electrically connected to a high power supply voltage line,
wherein the second shielding line includes a protrusion protruding and electrically connected to the high power supply voltage shorting bar.

10. The display device of claim 6, further comprising:
a horizontal signal line overlapping the plurality of link lines and extending in a direction parallel to the plurality of second signal lines,
wherein the second shielding line includes a protrusion protruding to and electrically connected to the horizontal signal line.

11. The display device of claim 10, wherein the horizontal signal line receives a signal from either a ground voltage or a low power supply voltage.

12. The display device of claim 1, further comprising:
an electrostatic discharge pattern disposed at a first end of the plurality of first signal lines,
wherein the first end of the plurality of first signal lines is disposed in an area facing the plurality of link lines.

13. The display device of claim 1, further comprising:
a bridge line extending in a first direction from the low power supply voltage contact part.

14. The display device of claim 13, wherein a first end of the bridge line is connected to the low power supply voltage contact part, and a second end of the bridge line coincides with an end of the substrate.

15. The display device of claim 13, wherein the bridge line is disposed on a different layer from the plurality of link lines.

16. A display device comprising:
a substrate including a display area having a light emitting pixels in the display area and including a non-display area;
a low power supply voltage contact part disposed in the non-display area;
a low power supply voltage line disposed in the non-display area connecting a pad electrode to the low power supply voltage contact part;
an electrode covering the low power supply voltage contact part electrically connecting the low power supply voltage contact part to cathode electrodes of the light emitting pixels; and
a bridge line disposed in the non-display area and electrically connected to the low power supply voltage contact part while not electrically connected to any pad electrode.

17. The display device of claim 16, wherein a first end of each of the low power supply voltage line and the bridge line is connected to the low power supply voltage contact part, and a second end of each of the low power supply voltage line and the bridge line coincides with an end of the substrate.

18. The display device of claim 16, wherein each of the low power supply voltage line and the bridge line is connected to the low power supply voltage contact part through a contact hole, and
wherein the low power supply voltage line and the bridge line include a same material in a same layer.

19. The display device of claim 16, wherein the low power supply voltage line is connected to the low power supply voltage contact part through a contact hole, and the bridge line is integrally formed with the low power supply voltage contact part.

20. A display device comprising:
a substrate including a display area having light emitting pixels and including a non-display area having a pad area and a link area between the display area and the pad area;
a low power supply voltage contact part and at least one a first high power supply voltage shorting bar disposed in the link area;
a plurality of first signal lines in the display area extending in a first direction and connected to the light emitting pixels;
a plurality of second signal lines in the display area extending in a second direction perpendicular to first direction and connected to the light emitting pixels;
a cathode electrode covering the display area and connected to low power supply voltage contact part in the link area via a connection overlapping the low power supply voltage contact part; and
a plurality of pad electrodes disposed in the pad area and arranged along the second direction, the plurality of pad electrodes including first pad electrodes, a second pad electrode, a third pad electrode, fourth pad electrodes, and fifth pad electrodes,
wherein the first pad electrodes are electrically connected to first signal lines via respective first link lines,
wherein the second pad electrode provides a reference voltage to the display area, wherein the third pad electrode provides a high power supply voltage to the first high power supply voltage shorting bar,
wherein the fourth pad electrodes provide a low power supply voltage to the low power supply voltage contact part, the low power supply voltage being lower than the high power supply voltage,
wherein the fifth pad electrodes are disposed between the fourth pad electrodes and the first pad electrodes with the fifth pad electrodes being electrically connected to each other via a shielding line, and
wherein the shielding line that extends from one fifth pad electrode into the link area, around the low power supply voltage contact part, and back to another fifth pad electrode sch that the shielding line is disposed between the first link lines and the low power supply voltage contact part in plan view to shield the first link lines from an influence of a voltage applied to the low power supply voltage contact part.
